(19) United States
(12) Patent Application Publication
(10) Pub. No.: US 2013/0155636 A1
(43) Pub. Date: Jun. 20, 2013

(54) DUMMY THROUGH-SILICON VIA CAPACITOR

(71) Applicant: Changyok Park, North York (CA)

(72) Inventor: Changyok Park, North York (CA)

(21) Appl. No.: 13/713,667

(22) Filed: Dec. 13, 2012

Related U.S. Application Data
(60) Provisional application No. 61/576,525, filed on Dec. 16, 2011.

(51) Int. Cl. H01L 23/538; H01R 4/00

(52) U.S. Cl. CPC H01L 23/5384; H01R 4/00
USPC 361/772; 257/621

(57) ABSTRACT

An integrated circuit device includes dummy through-silicon vias (TSVs) that can be connected to one or more voltage references, thereby increasing a capacitance associated with the integrated circuit device, such as a decoupling capacitance. In addition, the dummy TSVs can be distributed based on the distribution of active TSVs in the device, thus increasing the stability and performance of the TSV manufacturing process.

### BACKGROUND

1. Field of the Disclosure

The present disclosure generally relates to integrated circuit devices and more particularly to through-silicon vias of integrated circuit devices.

2. Description of the Related Art

An integrated circuit device is typically formed in layers, whereby the layers form the electronic components, such as transistors and capacitors, of the integrated circuit device. After formation, the integrated circuit can be stacked or otherwise physically arranged with one or more additional integrated circuits in an integrated circuit package. Through-silicon vias (TSVs) are sometimes used to connect layers of one or more integrated circuits in an integrated circuit package, thereby providing an electrical connection between the layers.

### BRIEF DESCRIPTION OF THE DRAWINGS

The present disclosure may be better understood, and its numerous features and advantages made apparent to those skilled in the art by referencing the accompanying drawings.

FIG. 1 is block diagram illustrating a portion of an integrated circuit device including a set of dummy TSVs in accordance with one embodiment of the present disclosure.

FIG. 2 is a block diagram of an integrated circuit device illustrating a distribution of active TSVs and dummy TSVs in accordance with one embodiment of the present disclosure.

FIG. 3 is a block diagram of an integrated circuit device illustrating dummy TSVs connected to different voltage references to provide a decoupling capacitance in accordance with one embodiment of the present disclosure.

FIG. 4 is a block diagram of an integrated circuit device illustrating dummy TSVs and a device substrate connected to different voltage references to provide a decoupling capacitance in accordance with one embodiment of the present disclosure.

FIG. 5 is a flow diagram of a method forming an integrated circuit device in accordance with one embodiment of the present disclosure.

The use of the same reference symbols in different drawings indicates similar or identical items.

### DETAILED DESCRIPTION

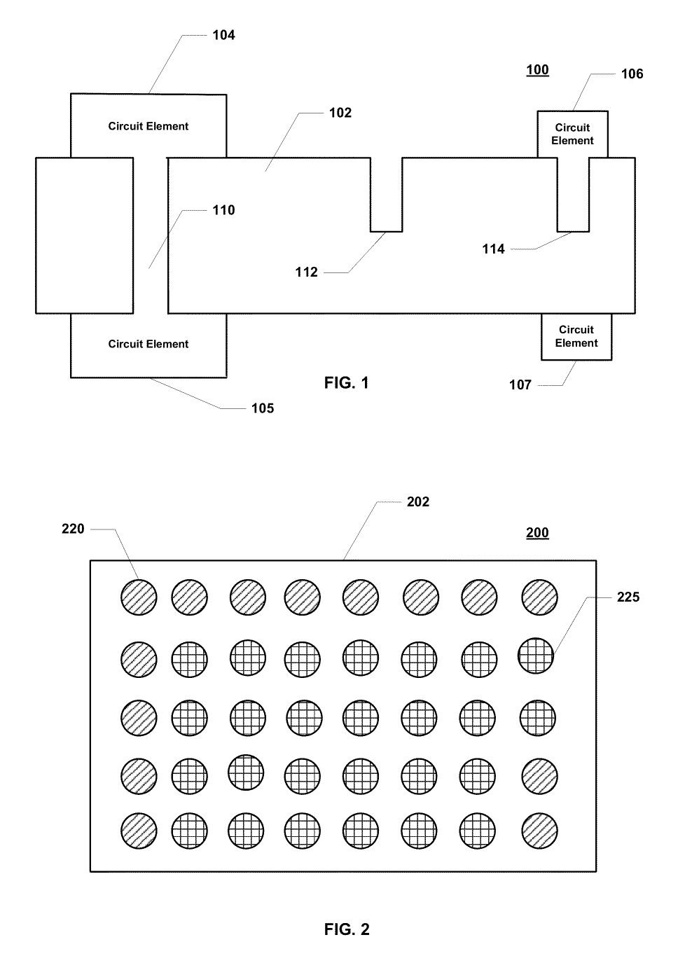

FIGS. 1-5 illustrate techniques for employing dummy through-silicon vias (TSVs) in an integrated circuit device. The dummy TSVs can be connected to one or more voltage references, thereby increasing a capacitance associated with the integrated circuit device, such as a decoupling capacitance. In addition, the dummy TSVs are distributed based on the distribution of active TSVs in the device, thus increasing the stability and performance of the TSV manufacturing process.

As used herein, an active TSV refers to a TSV that provides an electrical connection between components, such as transistors, of the integrated circuit device. An active TSV thus provides an electrical function for a circuit of the device. As used herein, a dummy TSV does not provide a connection between components of the integrated circuit device. The dummy TSV can affect the electrical properties of the integrated circuit device, such as a decoupling capacitance, but do not provide an electrical connection for a circuit of the device.

FIG. 1 illustrates a block diagram of a portion of an integrated circuit device 100 in accordance with one embodiment of the present disclosure. The integrated circuit device 100 can be formed to perform any one or more of a number of operations, such as data processing, electronic device control, signal processing, systems control, and the like. Accordingly, the integrated circuit device 100 can be a general purpose data processor, an application specific integrated circuit (ASIC), and the like. Further, the integrated circuit can be incorporated in any of a variety of electronic devices, such as a computer device, mobile phone, transportation device, portable electronic device, electronic control system, and the like.

In the illustrated embodiment, the integrated circuit device includes a substrate 102. In an embodiment, the substrate 102 is a silicon substrate upon which electronic circuits, each including a number of circuit elements are formed. For example, the integrated circuit device 100 includes circuit elements 104-107 formed on the substrate 102. Examples of circuit elements include transistors, passive elements such as capacitors, and the like. In an embodiment, the circuit elements 104-107 are formed by placing integrated circuit layers over the substrate 102.

In an embodiment, different integrated circuit dies are mounted on different sides of the substrate 102. Thus, for example, circuit elements 104 and 106 can be formed at one integrated circuit die on one side of the substrate 102 (illustrated in FIG. 1 as the top side) and circuit elements 105 and 107 formed at another integrated circuit die at the opposite side of the substrate 102 (illustrated in FIG. 1 as the bottom side). The integrated circuit dies and substrate 102 are encapsulated in an integrated circuit package, thereby forming the integrated circuit device 100.

Active TSVs can be placed in the substrate 102 to provide electrical connections between circuit elements of different integrated circuit dies. Thus, in the illustrated embodiment, active TSV 110 provides an electrical connection between the circuit element 104 and the circuit element 105.

In addition, dummy TSVs can be placed in the substrate 102. For example, in the embodiment of FIG. 1, the dummy TSVs 112 and 114 have been placed in substrate 102. The dummy TSVs 112 and 114 have different sizes, or depths, than the active TSV 110. In particular, the active TSV 110 is sized such that it traverses the thickness of the substrate 102 in order to provide the electrical connection between circuit elements 104 and 105. In contrast, the dummy TSVs 112 and 114 are sized such that each dummy TSV traverses approximately half of the thickness of the substrate 102. By forming the dummy TSVs to be smaller than the active TSVs, the dummy TSVs are prevented from establishing electrical connections between circuit elements. For example, the size of dummy TSV 114 is such that it cannot form an electrical connection between the circuit element 106 and the circuit element 107, even though it is between those circuit elements and is connected to circuit element 106.

Because the dummy TSVs are formed of a size such that they cannot form connections between circuit elements, they can be widely distributed through an integrated circuit device. This can be better understood with reference to FIG. 2, which illustrates a top view of a substrate 202 of integrated circuit device 200 in accordance with one embodiment of the present disclosure. In the illustrated embodiment, the circles represent TSVs formed at the substrate 202. In particular, circles filled with diagonal lines represent active TSVs, while circles filled with squares represent dummy TSVs. Thus, for example, TSV 220 is an active TSV and TSV 225 is a dummy TSV.

In the illustrated example of FIG. 2, the active TSVs and dummy TSVs are arranged such that, together, they have a substantially uniform spatial distribution across the surface of the substrate 202. As used herein, substantially uniform means that the distances between TSVs do not vary by more than 2 per cent. The substantially uniform distribution of TSVs can increase the process margin and stability of forming the integrated circuit device 200. In other embodiments, other distributions of TSVs can be implemented.

The integrated circuit 200 can be designed and formed in order to achieve the substantially uniform spatial distribution, or other desired distribution, of TSVs. For example, in one embodiment the integrated circuit 200 is designed by determining the spatial locations of each of the active TSVs. Based on the spatial distribution of the active TSVs, the spatial distribution of the dummy TSVs is determined in order to achieve the desired overall distribution of TSVs. The active and dummy TSVs are then placed at the substrate 202.

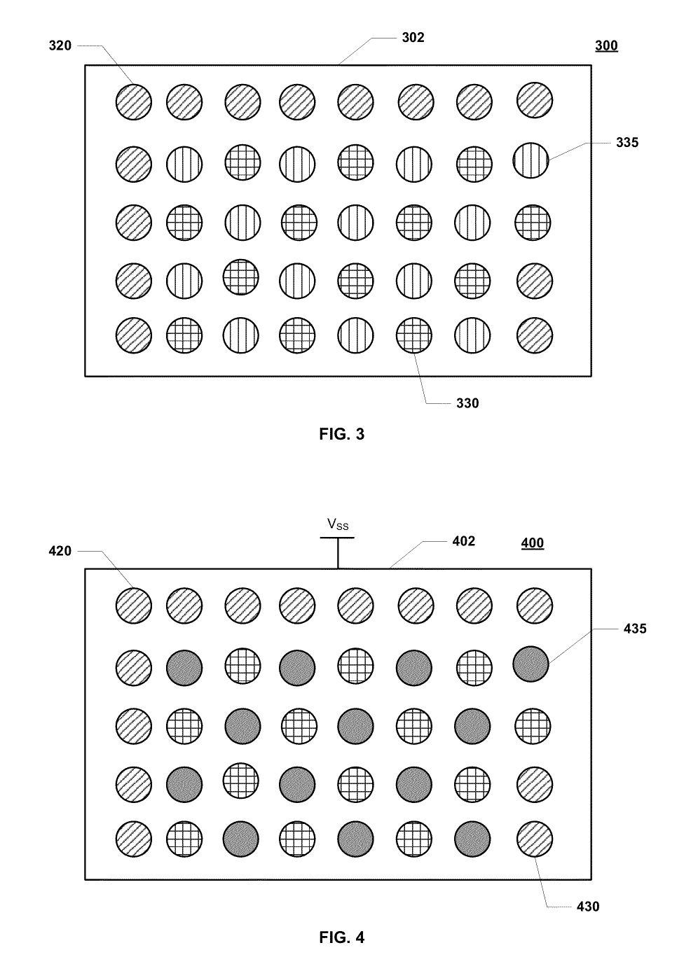

In an embodiment, the dummy TSVs can be connected to one or more reference voltages in order to set a decoupling capacitance for an integrated circuit device. This can be better understood with reference to FIG. 3, which illustrates a top view of a substrate 302 of integrated circuit device 300 in accordance with one embodiment of the present disclosure. In the illustrated embodiment, the circles represent TSVs formed at the substrate 302. In particular, circles filled with diagonal lines represent active TSVs, while circles filled with horizontal and vertical lines represent dummy TSVs connected to one reference voltage (e.g. V_{DD}), and circles filled with only vertical lines are connected to a different reference voltage (e.g. V_{SS}). Thus, for example, TSV 320 is an active TSV, TSV 330 is a dummy TSV connected to V_{DD} and TSV 335 is a dummy TSV connected to V_{SS}.

In the illustrated embodiment, approximately half of the dummy TSVs are connected to V_{DD} and approximately half are connected to V_{SS}. As used herein, approximately refers to being at a value within a tolerance of 2%. This connectivity of the dummy TSVs can increase the capacitance associated with the substrate 302, thereby reducing noise associated with particular circuit types such as power regulators, without requiring the formation of additional capacitors at the integrated circuit device 300. The dummy TSVs can thus be used to increase a decoupling capacitance associated with the integrated circuit device 300. In other embodiments, other ratios of dummy TSVs connected to V_{DD} and V_{SS} can be implemented in order to achieve a desired capacitance.

In another embodiment, the capacitance can be achieved by connecting a set of dummy TSVs to one voltage reference and connecting the substrate itself to another voltage reference. This can be better understood with reference to FIG. 4, which illustrates a top view of a substrate 402 of integrated circuit device 400 in accordance with one embodiment of the present disclosure. In the illustrated embodiment, the circles represent TSVs formed at the substrate 302. In particular, circles filled with diagonal lines represent active TSVs, while circles filled with horizontal and vertical lines represent dummy TSVs connected to one reference voltage (e.g. V_{DD}), and circles filled with solid gray are not connected to a voltage reference. Thus, for example, TSV 420 is an active TSV, TSV 430 is a dummy TSV connected to V_{DD} and TSV 435 is a dummy TSV not connected to a reference voltage. Further, in the illustrated example the substrate 402 is connected to a different reference voltage than any of the dummy TSVs (e.g. V_{SS}).

In the illustrated embodiment, approximately half of the dummy TSVs are connected to V_{DD} and approximately half not connected to a reference voltage. Further, the substrate 402 is connected to the V_{SS}. This connectivity of the dummy TSVs and the substrate can increase the capacitance associated with the substrate 402, In other embodiments, a different number of dummy TSVs can be connected to V_{DD} can be in order to achieve a desired capacitance.

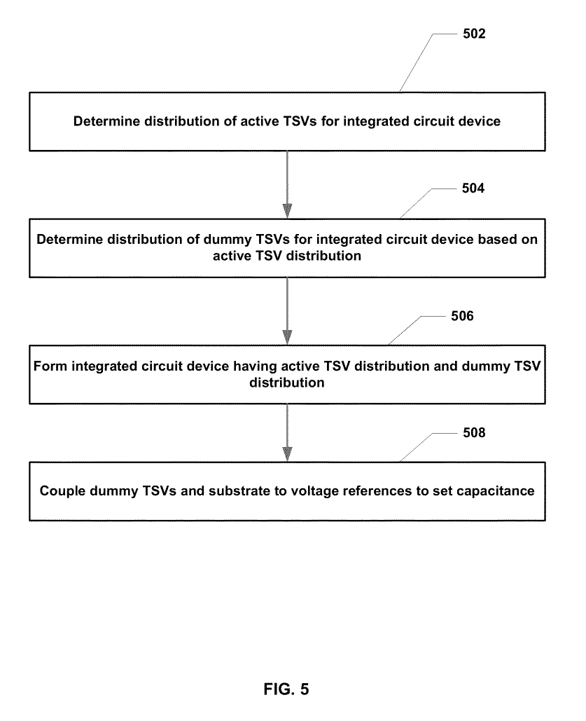

FIG. 5 illustrates a flow diagram of a method of forming an integrated circuit device to achieve a desired distribution of TSVs in accordance with one embodiment of the present disclosure. The method of claim 5 can be implemented at a computer device including a processor and a computer readable medium tangibly embodying a set of instructions that manipulate the processor in order to carry out the method.

At block 502 a distribution of active TSVs for an integrated circuit device are determined. This includes determining the relative spatial position of each active TSV at a substrate of the integrated circuit device. At block 504, a distribution of dummy TSVs is determined based on the distribution of active TSVs. The distribution of dummy TSVs is also based on a desired overall distribution of both active and dummy TSVs at the substrate, such as a substantially uniform distribution. At block 506, the integrated circuit device is formed, whereby the dummy and active TSVs are each located according to the determined distribution. At block 508, the dummy TSVs, a substrate of the integrated circuit device, or a combination thereof are coupled to one or more voltage references in order to set a capacitance, such as a decoupling capacitance, associated with the integrated circuit device.

As disclosed herein, in one embodiment a method includes coupling a first plurality of dummy through-silicon vias (TSVs) of an integrated circuit device to a first voltage reference to set a capacitance associated with the integrated circuit device. In one aspect, the method includes coupling a second plurality of dummy TSVs of the integrated circuit device to a second voltage reference to set the capacitance. In another aspect, the number of dummy TSVs of the first plurality of dummy TSVs is substantially the same as the number of TSVs of the second plurality of dummy TSVs. In yet another aspect, the method includes coupling a substrate of the integrated circuit device to a second voltage reference to set the capacitance, the plurality of dummy TSVs extending through at least a portion of the substrate. In still another aspect, the method includes spatially distributing the first plurality of dummy TSVs based on a spatial distribution of a plurality of active TSVs of the integrated circuit device. In another aspect, the first plurality of dummy TSVs have a different depth than the plurality of active TSVs. In another aspect spatially distributing the plurality of dummy TSVs includes spatially distributing the plurality of dummy TSVs such that the plurality of dummy TSVs and the plurality of active TSVs are together distributed in a substantially uniform distribution at a substrate of the integrated circuit device.

In another embodiment a method of forming an integrated circuit device includes forming the device to have a plurality of active TSVs and a plurality of dummy TSVs, and coupling a first subset of the plurality of dummy TSVs to a first voltage reference to set a capacitance associated with the integrated circuit device. In one aspect, the method includes coupling a second subset of the plurality of dummy TSVs to a second voltage reference to set the capacitance. In another aspect, the first subset consists of approximately half of the plurality of dummy TSVs. In yet another aspect, the second subset consists of approximately half of the plurality of dummy TSVs. In still another aspect, the method includes coupling a substrate of the integrated circuit device to a second voltage reference to set the capacitance, the plurality of dummy TSVs extending through at least a portion of the substrate. In another aspect, the plurality of dummy TSVs have a different depth than the plurality of active TSVs.

In an embodiment, an integrated circuit device includes a plurality of active TSVs and a plurality of dummy TSVs, a first subset of the plurality of dummy TSVs coupled to a first voltage reference to set a capacitance associated with the integrated circuit device. In one aspect, a second subset of the plurality of dummy TSVs is coupled to a second voltage reference to set the capacitance. In another aspect, the first subset consists of approximately half of the plurality of dummy TSVs. In still another aspect, the second subset consists of approximately half of the plurality of dummy TSVs. In yet another aspect, a substrate of the integrated circuit device is coupled to a second voltage reference to set the capacitance, the plurality of dummy TSVs extending through at least a portion of the substrate. In another aspect, the plurality of dummy TSVs have a different depth than the plurality of active TSVs. In still another aspect the capacitance is a decoupling capacitance of the integrated circuit device.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed.

Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

What is claimed is:

1. A method, comprising:
coupling a first plurality of dummy through-silicon vias (TSVs) of an integrated circuit device to a first voltage reference to set a capacitance associated with the integrated circuit device.

2. The method of claim 1, further comprising:
coupling a second plurality of dummy TSVs of the integrated circuit device to a second voltage reference to set the capacitance.

3. The method of claim 2, wherein the number of dummy TSVs of the first plurality of dummy TSVs is substantially the same as the number of TSVs of the second plurality of dummy TSVs.

4. The method of claim 1, further comprising:
coupling a substrate of the integrated circuit device to a second voltage reference to set the capacitance, the plurality of dummy TSVs extending through at least a portion of the substrate.

5. The method of claim 1, further comprising spatially distributing the first plurality of dummy TSVs based on a spatial distribution of a plurality of active TSVs of the integrated circuit device.

6. The method of claim 5, the first plurality of dummy TSVs having a different depth than the plurality of active TSVs.

7. The method of claim 5, wherein spatially distributing the plurality of dummy TSVs comprises spatially distributing the plurality of dummy TSVs such that the plurality of dummy TSVs and the plurality of active TSVs are together distributed in a substantially uniform distribution at a substrate of the integrated circuit device.

8. A method, comprising forming an integrated circuit device to have a plurality of active TSVs and a plurality of dummy TSVs, and coupling a first subset of the plurality of dummy TSVs to a first voltage reference to set a capacitance associated with the integrated circuit device.

9. The method of claim 8, further comprising coupling a second subset of the plurality of dummy TSVs to a second voltage reference to set the capacitance.

10. The method of claim 9, wherein the first subset consists of approximately half of the plurality of dummy TSVs.

11. The method of claim 10, wherein the second subset consists of approximately half of the plurality of dummy TSVs.

12. The method of claim 8, further comprising coupling a substrate of the integrated circuit device to a second voltage reference to set the capacitance, the plurality of dummy TSVs extending through at least a portion of the substrate.

13. The method of claim 8, wherein the plurality of dummy TSVs have a different depth than the plurality of active TSVs.

14. An integrated circuit device comprising a plurality of active TSVs and a plurality of dummy TSVs, a first subset of the plurality of dummy TSVs coupled to a first voltage reference to set a capacitance associated with the integrated circuit device.

15. The integrated circuit device of claim 14, wherein a second subset of the plurality of dummy TSVs is coupled to a second voltage reference to set the capacitance.

16. The integrated circuit device of claim 14, wherein the first subset consists of approximately half of the plurality of dummy TSVs.

17. The integrated circuit device of claim 16, wherein the second subset consists of approximately half of the plurality of dummy TSVs.

18. The integrated circuit device of claim 14, wherein a substrate of the integrated circuit device is coupled to a second voltage reference to set the capacitance, the plurality of dummy TSVs extending through at least a portion of the substrate.

19. The integrated circuit device of claim 14, wherein the plurality of dummy TSVs have a different depth than the plurality of active TSVs.

20. The integrated circuit device of claim 14, wherein the capacitance is a decoupling capacitance of the integrated circuit device.
